(19) United States
(12) Patent Application Publication
(10) Pub. No.: US 2015/0029668 A1
(43) Pub. Date: Jan. 29, 2015

(54) Clamping Structure for Power Electronic Components

(71) Applicant: Aura Systems, Inc., El Segundo, CA (US)

(72) Inventors: Si Ryong Yu, Gyeonggi-do (KR); Guanghui Wang, Torrance, CA (US)

(21) Appl. No.: 13/950,244

(22) Filed: Jul. 24, 2013

(51) Int. Cl. H05K 7/02; H05K 7/20

(52) U.S. Cl. CPC H05K 7/02; H05K 7/2039
USPC 361/704; 361/679.01; 248/316.1

(57) ABSTRACT

A clamping structure, including a base defined by a height, the base including a first end and a second end, wherein the first end and the second end are on opposite sides of one another; a first end wall situated on the first end of the base and a second end wall situated on the second end of the base; and at least one wall partition situated on the base between the first end wall and the second end wall to form the border of a first receiving area with the first end wall; wherein the first receiving area is generally rectangular or generally square in shape and includes two openings on two sides not bordered by either the at least one wall partition or the first end wall.

### FIELD

This disclosure relates generally to a clamping structure. More particularly, the disclosure relates to a clamping structure for power electronic components.

### BACKGROUND

Power electronic components are commonly used on integrated circuit modules (ICMs) or printed circuit boards (PCBs). Often, heat dissipation is a challenging issue especially when there are numerous power electronic components mounted in close proximity to one another on an ICM or a PCB. In some cases, due to differences in the height dimension of multiple power electronic components on an ICM or PCB, some of the power electronic components may not align well with a thermal pad or heat sink pad for optimum heat transfer for optimum heat dissipation. Thus, it would be desirable to mitigate height differences and/or close proximity issues of the multiple power electronic components mounted on a printed circuit board (PCB) to optimize heat dissipation. In one example, the PCB is an integrated circuit module (ICM).

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

Disclosed is a clamping structure for improved heat dissipation of power electronic components. According to one aspect, a clamping structure, including a base defined by a height, the base including a first end and a second end, wherein the first end and the second end are on opposite sides of one another; a first end wall situated on the first end of the base and a second end wall situated on the second end of the base; and at least one wall partition situated on the base between the first end wall and the second end wall to form the border of a first receiving area with the first end wall; wherein the first receiving area is generally rectangular or generally square in shape and includes two openings on two sides not bordered by either the at least one wall partition or the first end wall.

According to another aspect, a clamping structure, including a base defined by a height, the base including a first end and a second end, wherein the first end and the second end are on opposite sides of one another; a first end wall situated on the first end of the base and a second end wall situated on the second end of the base; and at least three wall partitions situated on the base between the first end wall and the second end wall, wherein each of the at least three wall partitions are equally spaced from each other; wherein a first of the at least three wall partitions and the first end wall defines a first receiving area, the first of the at least three wall partitions and a second of the at least three wall partitions defines a second receiving area, the second of the at least three wall partitions and a third of the at least three wall partitions defines a third receiving area, and the third of the at least three wall partitions and the second end wall defines a fourth receiving area; and wherein the first, second, third and fourth receiving areas are generally rectangular or generally square in shape and each of the receiving areas includes two openings on opposite sides of each other.

According to another aspect, a clamping structure, including a base defined by a height, the base including a first end and a second end, wherein the first end and the second end are on opposite sides of one another; a first end wall situated on the first end of the base and a second end wall situated on the second end of the base; and at least one wall partition situated on the base between the first end wall and the second end wall to form the border of a first receiving area with the first end wall; wherein the first receiving area is generally elliptical in shape and includes an opening for connecting at least one electrical lead to a power electronic component housed within the first receiving area.

Advantages of the present disclosure may include better physical contact between a power electronic component and a thermal pad or heat dissipation pad, and improvement in heat dissipation for the power electronic component.

It is understood that other aspects will become readily apparent to those skilled in the art from the following detailed description, wherein it is shown and described various aspects by way of illustration. The drawings and detailed description are to be regarded as illustrative in nature and not as restrictive.

### BRIEF DESCRIPTION OF THE DRAWINGS

FIG. 1 illustrates a side view of an example of a clamping structure.

FIG. 2 illustrates a top view of the example of the clamping structure of FIG. 1.

FIG. 3 illustrates a side view example of a clamping structure with power electronic components housed in the receiving areas.

FIG. 4 illustrates a top view of four clamping structures, each with power electronic components housed in the respective receiving areas.

FIG. 5 illustrates a top view of the example of a clamping structure with elliptical receiving area.

### DETAILED DESCRIPTION

The detailed description set forth below in connection with the appended drawings is intended as a description of various aspects of the present disclosure and is not intended to represent the only aspects in which the present disclosure may be practiced. Each aspect described in this disclosure is provided merely as an example or illustration of the present disclosure, and should not necessarily be construed as preferred or advantageous over other aspects. The detailed description includes specific details for the purpose of providing a thorough understanding of the present disclosure. However, it will be apparent to those skilled in the art that the present disclosure may be practiced without these specific details. In some instances, well-known structures and devices are shown in block diagram form in order to avoid obscuring the concepts of the present disclosure. Acronyms and other descriptive terminology may be used merely for convenience and clarity and are not intended to limit the scope of the present disclosure.

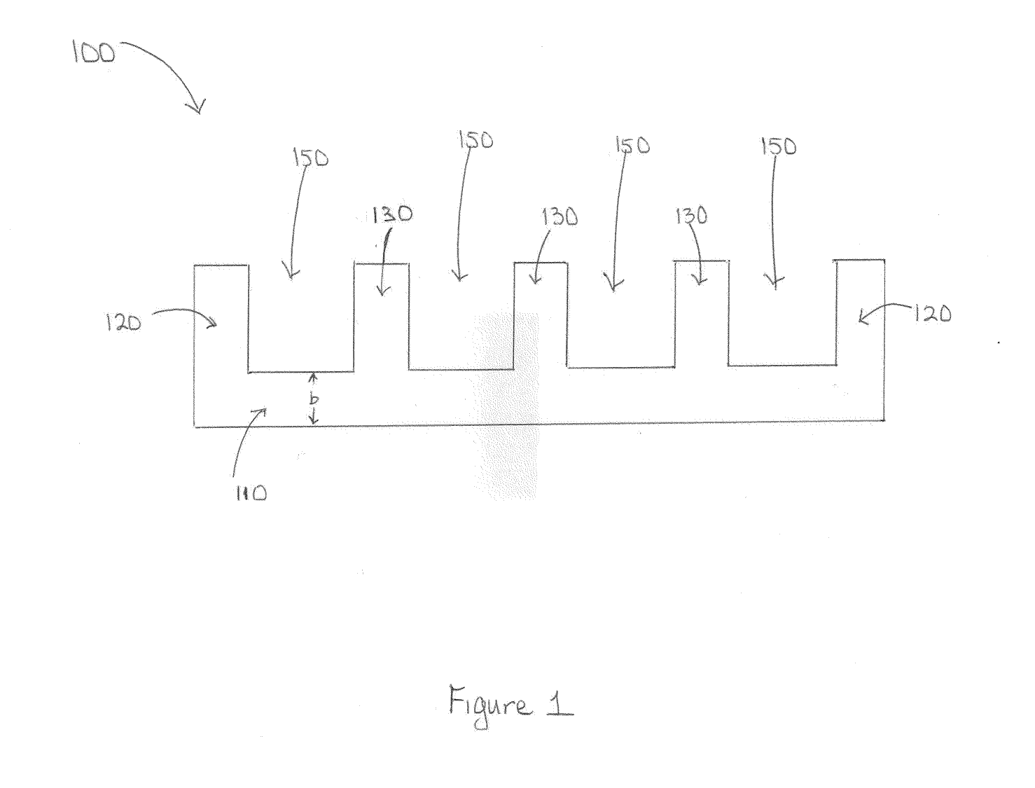

FIG. 1 illustrates a side view of an example of a clamping structure 100. In one example, the clamping structure 100 includes a base 110, two end walls 120, and at least one wall partition 130. The wall partition 130 and the end walls 120 define a plurality of receiving areas 150. In one example, the end walls 120, and the wall partition 130 includes mounting holes (not shown) for fixing the clamping structure 100 to a printed circuit board (PCB) or an integrated circuit module (ICM). For example, the mounting holes may include threads for fixing the clamping structure 100 to a PCB or an ICM with screws and/or washers. With the ability to fix the clamping structure 100 to the PCB or the ICM, the PCB or the ICM may be handled freely without risk of dropping the clamping structure 100. In one example, the mounting holes may be used to mount the PCB or the ICM to a heat dissipation plate 320. In another example, by tightening the screws and/or washers through the mounting holes, pressure may be applied (or increased) to the power electronics component surfaces 315. In one example, separating the clamp structure mounting and the PCB/ICM mounting increases manufacturing efficiency.

The plurality of receiving areas 150 house power electronic components, for example, insulated gate bipolar transistors (IGBTs), switching components, etc. In one example, the power electronic components include an insulated gate bipolar transistor (IGBT). One skilled in the art would understand that other types of electronic components (even though not mentioned herein) may be housed within the receiving areas and still be within the scope and spirit of the present disclosure.

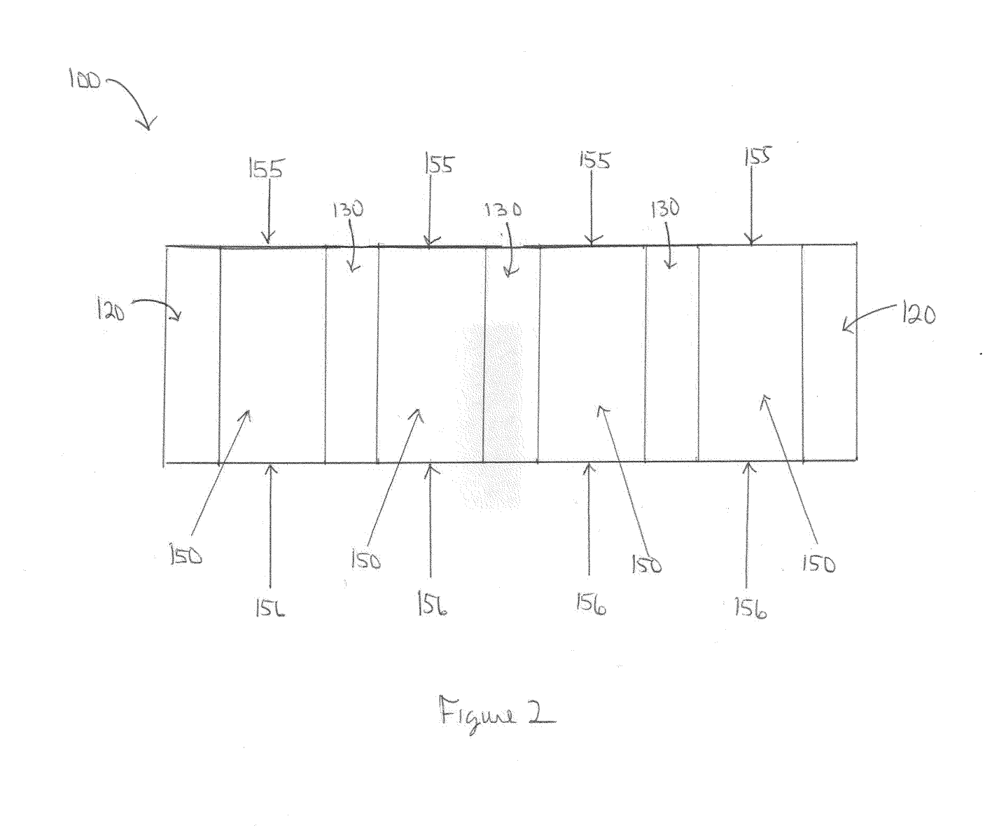

FIG. 2 illustrates a top view of the example of the clamping structure 100 of FIG. 1. As shown in FIG. 2, the receiving area 150 includes two openings 155, 156 that are directly opposite each other. The openings 155,156 are not bordered by a structure (e.g., end wall or wall partition). One skilled in the art would understand that the clamping structure 100 is not limited to two openings. In one example, the clamping structure 100 may include only one opening. In another example, the receiving area 150 may include more than two openings.

In the example illustrated in FIG. 2, the receiving area 150 is generally rectangular or square in shape. In this example, the receiving area 150 includes two openings 155, 156 on opposite sides with the other two remaining sides of the receiving area 150 being bordered by either an end wall 120 and a wall partition 130, or by two wall partitions 130. For example, in the example of four receiving areas 150, the first and last receiving areas in a series are each bordered by an end wall 120 and a wall partition 130. However, the intermediate receiving areas (i.e., the second and third receiving areas) are each bordered by two wall partitions 130. Although four receiving areas 150 are shown in FIGS. 1 and 2, one skilled in the art would understand that the quantity of receiving areas 150 may vary (and is not limited to four) according to need and application of a particular device.

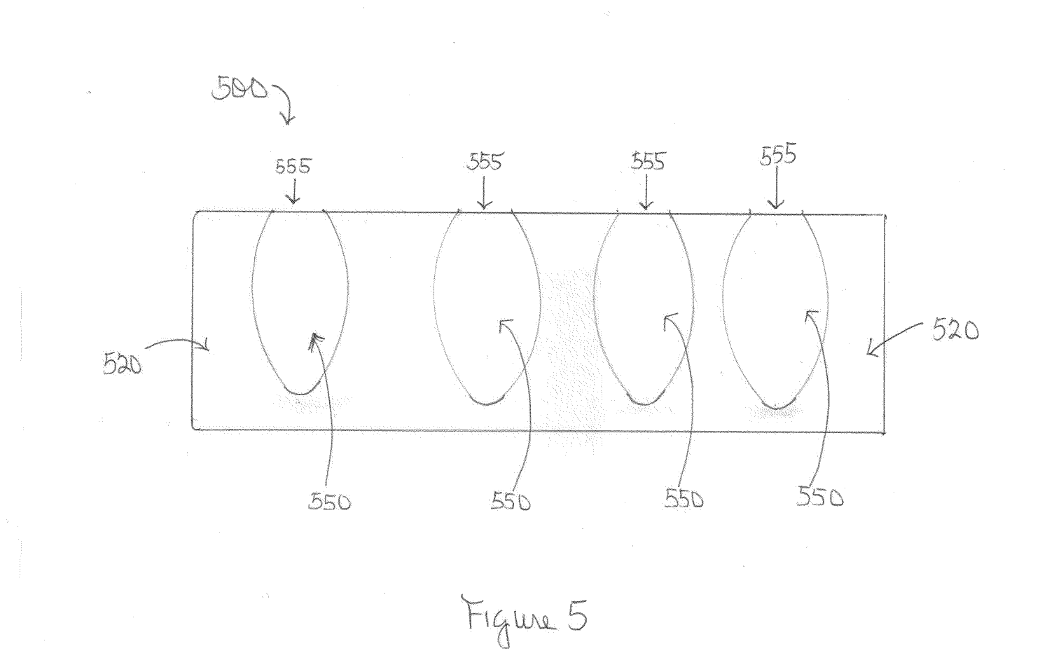

In another example, the receiving area may be generally elliptical or circular in shape. FIG. 5 illustrates a top view of the example of a clamping structure 500 with generally elliptical receiving areas 550. A generally circular receiving area is another example of a generally elliptical receiving area. In the example of FIG. 5, the receiving area 550 may include one opening 555 with the rest of the generally elliptical shape being bordered by one or more structures 520. In the example, of FIG. 5, the receiving areas are not equally spaced from each other. However, in another example, the receiving areas 550 are equally spaced from each other.

In one example, the height (b) of the base as shown in FIG. 1 is generally uniform. And, if the height dimension of the power electronic components housed within the receiving areas 150 is uniform, then uniform alignment is achieved between a top face 315 of the power electronic components and a heat dissipation plate 320. In another example, the height (b) of the base is non-uniform. In one example, the non-uniformity of the height (b) of the base allows alignment of top face 315 of the power electronic components with a heat dissipation plate 320. For example, the height (b) of the base is varied to achieve the alignment.

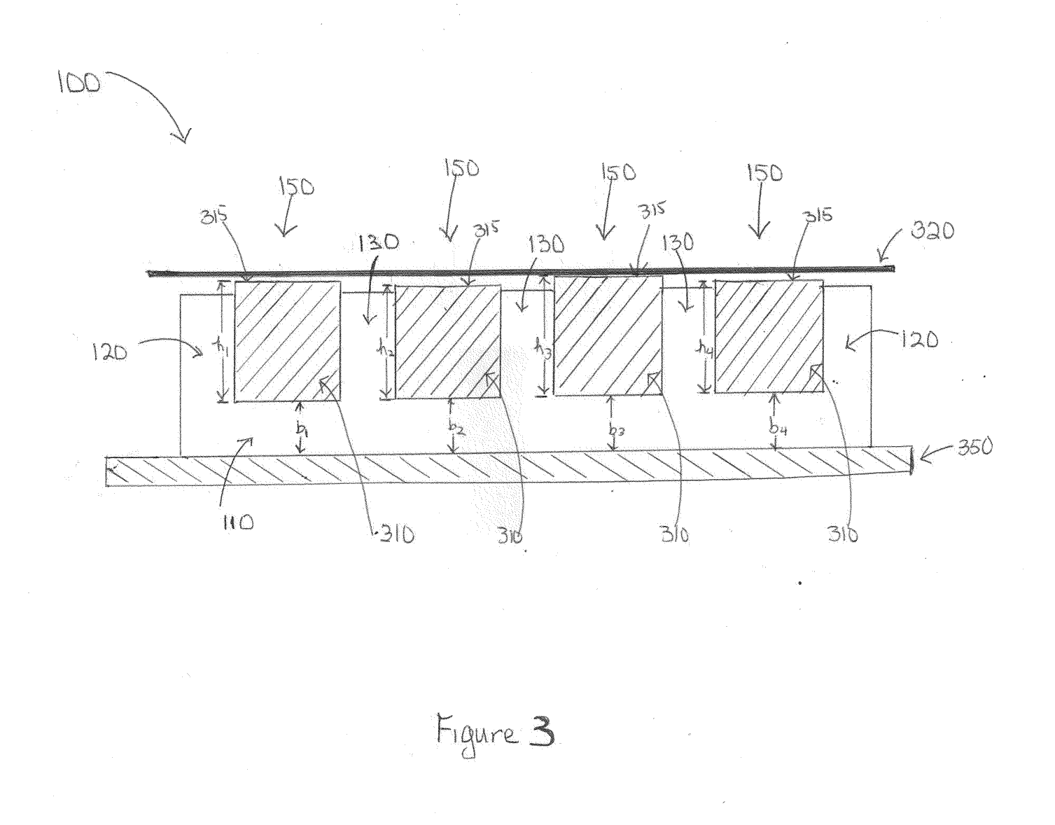

FIG. 3 illustrates a side view example of a clamping structure 100 with power electronic components 310 housed in the receiving areas 150. In the example of FIG. 3, the height dimension of the power electronic components 310 varies. That is, h₁, h₂, h₃, and h₄ are different in height. Thus, to achieve a uniform alignment of the power electronic components to a heat dissipation plate 320, the base height dimensions b₁, b₂, b₃ and b₄ are varied conversely to the height dimension (h₁, h₂, h₃, and h₄) of the power electronic components 310. For example, b₁+h₁=b₂+h₂=b₃+h₃=b₄+h₄. By varying the base height dimensions b₁, b₂, b₃ and b₄, the top face 315 of each of the power electronic components is aligned to the heat dissipation plate 320. In one example, the amount of variation of each of the base height dimensions b₁, b₂, b₃ and b₄ is conversely dependent on the variations of the height dimension (h₁, h₂, h₃, and h₄) of the power electronic components 310 such that each sum bᵢ+hᵢ generally equals a constant.

In one example, the clamping structure 100 is a single piece structure. In one example, the clamping structure 100 is composed of an insulation material, for example, a polymer. In one example, the clamping structure 100 is composed of one or more of the following material: rubber, plastic, polymer insulators, silicone rubber insulators or combination thereof. One skilled in the art would understand that the list of materials disclosed herein for the clamping structure is not an exclusive list and that other materials (whether it is an insulating material or a conductive material) may be used depending on the particular application.

In one example, the clamping structure 100 sits on top of a printed circuit board (PCB) 350. In one example, the PCB is an integrated circuit module (ICM). In this example, the power electronic components 310 are elevated from the PCB by being housed in the receiving area 150 of the clamping structure 100.

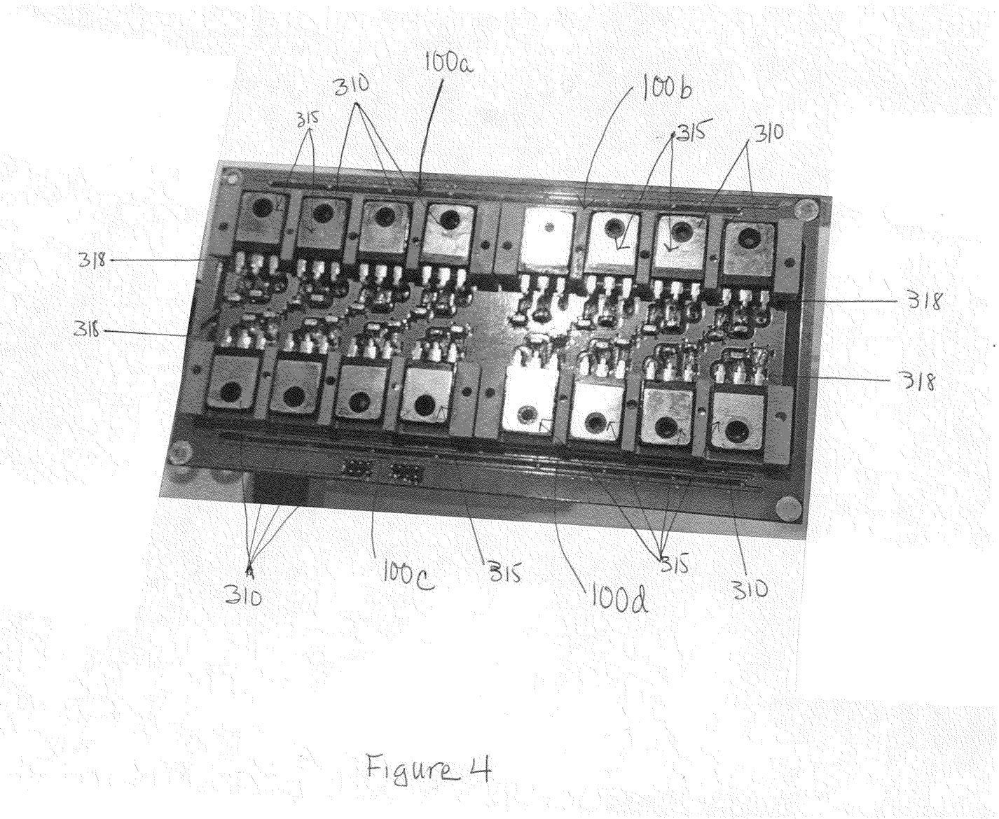

FIG. 4 illustrates a top view of four clamping structures 100a, 100b, 100c, 100d, each with power electronic components 310 housed in the respective receiving areas 150. FIG. 4 shows four clamping structures, two on one side and two on another side. In the example of FIG. 4, each of the clamping structures houses four power electronic components. The top face 315 of each of the power electronic components 310 is shown in FIG. 4. In one example, the top face 315 conducts heat away from the power electronic components. For example, a heat dissipation plate 320 (shown in FIG. 3) contacts with the top face 315 to dissipate heat generated by the power electronic components 310.

Also shown in FIG. 4 are electrical leads 318 that couple the power electronic components 310 to the PCB 350. In one example, the power electronic components 310 sit above the base 110 of the clamping structure 100 in the receiving area 150. Since the power electronic components 310 are elevated at least by the height of the base (b) from the printed circuit board (PCB) 350, the electrical leads 318 also rise above the PCB 350 to connect with the power electronic components 310, for example, by at least the height of the base (b).

Although FIG. 4 illustrates four clamping structures, two adjacent clamping structures situated opposite two other adjacent clamping structures, one skilled in the art would understand that the arrangement and quantity of clamping structures illustrated in FIG. 4 is merely an example. Other quantities and arrangements of multiple clamping structures are also within the scope and spirit of the present disclosure. For example, four clamping structures could be placed adjacent to one another in a row. Or, there could be six clamping structures with three rows of two clamping structures adjacent to one another. Other arrangements of clamping structures are possible and suitable for particular applications.

The previous description of the disclosed aspects is provided to enable any person skilled in the art to make or use the present disclosure. Various modifications to these aspects will be readily apparent to those skilled in the art, and the generic principles defined herein may be applied to other aspects without departing from the spirit or scope of the disclosure.

1. A clamping structure, comprising:
a base defined by a height, the base including a first end and a second end, wherein the first end and the second end are on opposite sides of one another;
a first end wall situated on the first end of the base and a second end wall situated on the second end of the base; and
at least one wall partition situated on the base between the first end wall and the second end wall to form the border of a first receiving area with the first end wall;
wherein the first receiving area is generally rectangular or generally square in shape and includes two openings on two sides not bordered by either the at least one wall partition or the first end wall.

2. The clamping structure of claim 1, wherein the at least one wall partition forms the border of a second receiving area with the second end wall.

3. The clamping structure of claim 2, wherein the height of the base is different at the first receiving area and at the second receiving area.

4. The clamping structure of claim 2, wherein the first receiving area houses a first power electronic component and the second receiving area houses a second power electronic component.

5. The clamping structure of claim 4, wherein the height of the base varies conversely with a first dimension of the first power electronic component and a second dimension of the second power electronic component to align the first and second power electronic components with a heat dissipation plate.

6. The clamping structure of claim 5, wherein the first power electronic component includes an insulated gate bipolar transistor (IGBT).

7. The clamping structure of claim 1, wherein the height of the base is constant throughout the base.

8. The clamping structure of claim 7, wherein the clamping structure is a single piece of structure composed of an insulation material.

9. The clamping structure of claim 8, wherein at least one electrical lead is connected through one of the two openings to a power electronic component housed in the first receiving area.

10. The clamping structure of claim 9, wherein the power electronic component includes an insulated gate bipolar transistor (IGBT).

11. The clamping structure of claim 10, wherein a top face of the power electronic component is aligned to a heat dissipation plate.

12. A clamping structure, comprising:
a base defined by a height, the base including a first end and a second end, wherein the first end and the second end are on opposite sides of one another;
a first end wall situated on the first end of the base and a second end wall situated on the second end of the base; and
at least three wall partitions situated on the base between the first end wall and the second end wall, wherein each of the at least three wall partitions are equally spaced from each other;
wherein a first of the at least three wall partitions and the first end wall defines a first receiving area, the first of the at least three wall partitions and a second of the at least three wall partitions defines a second receiving area, the second of the at least three wall partitions and a third of the at least three wall partitions defines a third receiving area, and the third of the at least three wall partitions and the second end wall defines a fourth receiving area; and
wherein the first, second, third and fourth receiving areas are generally rectangular or generally square in shape and each of the receiving areas includes two openings on opposite sides of each other.

13. The clamping structure of claim 12, wherein the clamping structure is a single piece of structure composed of an insulation material.

14. The clamping structure of claim 13, wherein the height of the base is constant throughout the base.

15. The clamping structure of claim 12, wherein the first, second, third and fourth receiving areas each houses a first power electronic component, a second power electronic component, a third power electronic component and a fourth power electronic component, respectively.

16. The clamping structure of claim 15, wherein at least one of the first power electronic component, the second power electronic component, the third power electronic component or the fourth power electronic component is an insulated gate bipolar transistor (IGBT).

17. The clamping structure of claim 15, wherein the height of the base is non-uniform.

18. The clamping structure of claim 15, wherein the height of the base varies conversely with a first dimension of the first power electronic component, a second dimension of the second power electronic component, a third dimension of the third power electronic component, and a fourth dimension of the fourth power electronic component.

19. A clamping structure, comprising:
a base defined by a height, the base including a first end and a second end, wherein the first end and the second end are on opposite sides of one another;
a first end wall situated on the first end of the base and a second end wall situated on the second end of the base; and
at least one wall partition situated on the base between the first end wall and the second end wall to form the border of a first receiving area with the first end wall;
wherein the first receiving area is generally elliptical in shape and includes an opening for connecting at least one electrical lead to a power electronic component housed within the first receiving area.

20. The clamping structure of claim 19, wherein the height is defined to allow a top face of the power electronic component to be aligned to a heat dissipation plate.
